(19) United States
(12) Patent Application Publication
(10) Pub. No.: US 2021/0110999 A1
(43) Pub. Date: Apr. 15, 2021

(54) PLASMA PROCESSING APPARATUS

(71) Applicant: Tokyo Electron Limited, Tokyo (JP)

(72) Inventors: Taro IKEDA, Yamanashi (JP); Hiroki EHARA, Yamanashi (JP)

(21) Appl. No.: 17/063,088

(22) Filed: Oct. 5, 2020

(30) Foreign Application Priority Data
Oct. 11, 2019 (JP) 2019-188104

(51) Int. Cl. H01J 37/32

(52) U.S. Cl. CPC H01J 37/3244; H01J 37/3222

(57) ABSTRACT

A plasma processing apparatus includes: a processing container; and a plurality of gas nozzles protruding from at least one of a top wall and a side wall that constitute the processing container, and including a gas supply hole configured to supply a gas into the processing container. The plurality of gas nozzles include an enlarged diameter portion that is enlarged from a pore of the gas supply hole at a tip end of the gas supply hole of the plurality of gas nozzles, and is opened to a processing space.

### CROSS-REFERENCE TO RELATED APPLICATIONS

This application is based on and claims priority from Japanese Patent Application No. 2019-188104 filed on Oct. 11, 2019 with the Japan Patent Office, the disclosure of which is incorporated herein in its entirety by reference.

### TECHNICAL FIELD

The present disclosure relates to a plasma processing apparatus.

### BACKGROUND

In a plasma processing apparatus, electromagnetic wave energy is concentrated in the vicinity of an electromagnetic wave radiation port provided in a top wall, and thus, electron temperature tends to increase. At this time, when a gas ejecting port exists in the vicinity of the electromagnetic wave radiation port, the gas may excessively decompose. Japanese Patent Laid-Open Publication No. 2014-183297 proposes to introduce a gas from a shower plate, and introduce a gas to the below of a microwave radiation port from an injection port of a gas nozzle that vertically protrudes downward from the lower surface of the shower plate. However, the microwave may be transmitted to the gas nozzle, and abnormal discharge may occur at the injection port of the gas nozzle, which may affect the substrate processing.

### SUMMARY

According to an aspect of the present disclosure, a plasma processing apparatus including: a processing container; and a plurality of gas nozzles protruding from an top wall and/or a side wall that constitute the processing container, and including a gas supply hole configured to supply a gas into the processing container is provided. Each of the plurality of gas nozzles includes an enlarged diameter portion that is enlarged from a pore of the gas supply hole at a tip end of the gas supply hole, and is opened to a processing space.

The foregoing summary is illustrative only and is not intended to be in any way limiting. In addition to the illustrative aspects, embodiments, and features described above, further aspects, embodiments, and features will become apparent by reference to the drawings and the following detailed description.

### BRIEF DESCRIPTION OF THE DRAWINGS

FIG. 1 is a schematic cross-sectional view illustrating an example of a plasma processing apparatus according to an embodiment.

FIG. 2 is an explanation view illustrating a configuration of a control unit illustrated in FIG. 1.

FIG. 3 is an explanation view illustrating a configuration of a microwave introducing module illustrated in FIG. 1.

FIG. 4 is a cross-sectional view illustrating a microwave introducing mechanism illustrated in FIG. 3.

FIG. 5 is a perspective view illustrating an antenna of the microwave introducing mechanism illustrated in FIG. 4.

FIG. 6 is a plan view illustrating a planar antenna of the microwave introducing mechanism illustrated in FIG. 4.

FIG. 7 is a bottom view of a top wall of a processing container illustrated in FIG. 1.

FIGS. 8A to 8D are views illustrating examples of a structure of a gas nozzle according to an embodiment.

FIGS. 9A to 9D are views illustrating an example of a structure of a gas nozzle according to Modification 1 of the embodiment.

FIGS. 10A to 10E are views illustrating examples of a structure of gas nozzles according to Modifications 2 to 6 of the embodiment.

### DETAILED DESCRIPTION

In the following detailed description, reference is made to the accompanying drawings, which form a part hereof. The illustrative embodiments described in the detailed description, drawing, and claims are not meant to be limiting. Other embodiments may be utilized, and other changes may be made without departing from the spirit or scope of the subject matter presented here.

Hereinafter, embodiments of the present disclosure will be described with reference to the drawings. In each drawing, the same components may be denoted by the same reference numerals, and duplicate description may be omitted.

[Plasma Processing Apparatus]

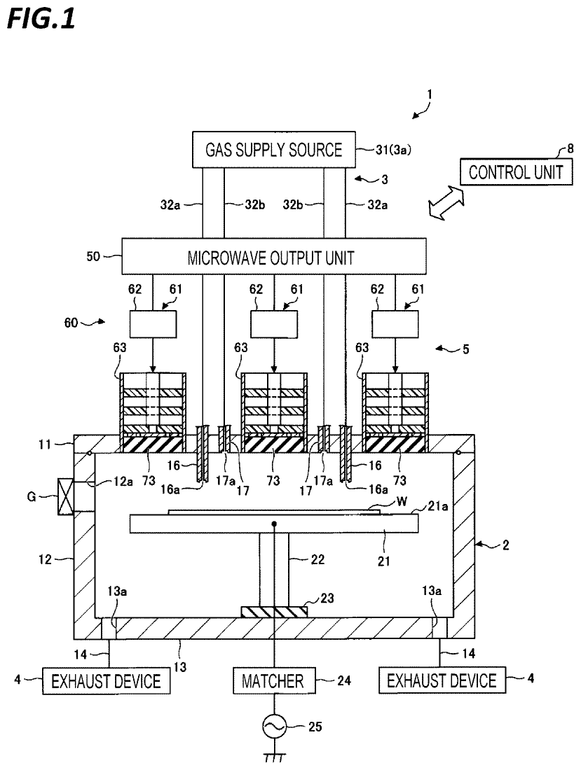

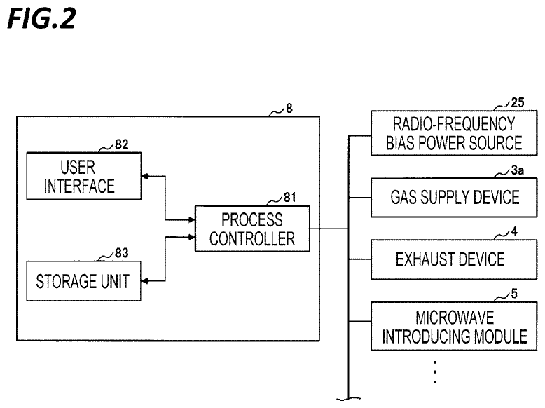

First, a schematic configuration of a plasma processing apparatus 1 according to an embodiment will be described with reference to FIGS. 1 and 2. FIG. 1 is a schematic cross-sectional view illustrating an example of the plasma processing apparatus 1 according to the embodiment. FIG. 2 is an explanation view illustrating an example of a configuration of a control unit 8 illustrated in FIG. 1. The plasma processing apparatus 1 according to the embodiment is an apparatus configured to perform a predetermined processing such as a film forming processing, a diffusion processing, an etching processing, and an ashing processing on, for example, a substrate W having a semiconductor wafer for manufacturing a semiconductor device as an example, with a plurality of continuous operations.

The plasma processing apparatus 1 includes a processing container 2, a stage 21, a gas supply mechanism 3, an exhaust device 4, a microwave introducing module 5, and a control unit 8. The processing container 2 accommodates the wafer W that is a processing target. The stage 21 is disposed inside the processing container 2, and includes a placing surface 21a on which the substrate W is placed. The gas supply mechanism 3 supplies a gas into the processing container 2. The exhaust device 4 exhausts the inside of the processing container 2 to reduce the pressure. The microwave introducing module 5 introduces a microwave for generating a plasma into the processing container 2. The control unit 8 controls each part of the plasma processing apparatus 1.

The processing container 2 has, for example, a substantially cylindrical shape. The processing container 2 is made of, for example, a metal material such as aluminum and an alloy thereof. The microwave introducing module 5 is disposed above the processing container 2, and functions as a plasma generating unit that introduces an electromagnetic wave (microwave in the embodiment) into the processing container 2 to generate a plasma.

The processing container 2 includes a plate-shaped top wall 11, a bottom wall 13, and a side wall 12 that connects the top wall 11 and the bottom wall 13. The top wall 11 includes a plurality of openings. The side wall 12 includes a carry-in/carry-out port 12a configured to perform the carry-in/carry-out of the substrate W to/from a transfer chamber (not illustrated) adjacent to the processing container 2. A gate valve G is disposed between the processing container 2 and the transfer chamber (not illustrated). The gate valve G has a function of opening/closing the carry-in/carry-out port 12a. The gate valve G hermetically seals the processing container 2 in the closed state, and enables the transfer of the substrate W between the processing container 2 and the transfer chamber (not illustrated) in the opened state.

The bottom wall 13 includes a plurality of (two in FIG. 1) exhaust ports 13a. The plasma processing apparatus 1 further includes an exhaust pipe 14 that connects the exhaust port 13a and the exhaust device 4. The exhaust device 4 includes an APC valve and a high-speed vacuum pump capable of reducing the pressure of the internal space of the processing container 2 to a predetermined vacuum degree with a high-speed. The example of the high-speed vacuum pump includes a turbo molecular pump. The pressure of the internal space of the processing container 2 is reduced to a predetermined vacuum degree, for example, 0.133 Pa, by operating the high-speed vacuum pump of the exhaust device 4.

The plasma processing apparatus 1 includes a support member 22 that supports the stage 21 in the processing container 2, and an insulating member 23 provided between the support member 22 and the bottom wall 13. The stage 21 is configured to horizontally place the substrate W. The support member 22 has a cylindrical shape extending from the center of the bottom wall 13 toward the internal space of the processing container 2. The stage 21 and the support member 22 are made of, for example, aluminum having a surface to which an alumite processing (anodizing processing) is performed.

The plasma processing apparatus 1 further includes a radio-frequency bias power source 25 that supplies a radio-frequency power to the stage 21, and a matcher 24 provided between the stage 21 and the radio-frequency bias power source 25. The radio-frequency bias power source 25 supplies a radio-frequency power to the stage 21 to attract ions to the substrate W. The matcher 24 includes a circuit configured to match the output impedance of the radio-frequency bias power source 25 and the impedance of the load side (the stage 21 side).

The plasma processing apparatus 1 may further include a temperature control mechanism (not illustrated) that heats or cools the stage 21. The temperature control mechanism controls, for example, the temperature of the substrate W within a range of 25° C. (room temperature) to 900° C.

The plasma processing apparatus 1 further includes a plurality of gas nozzles 16 and a plurality of gas introducing pipes 17. The plurality of gas nozzles 16 form a cylindrical shape, and protrude in a vertical direction from a lower surface of the top wall 11 that constitutes the processing container 2. The gas nozzles 16 supply a first gas into the processing container 2 from gas supply holes 16a formed at the tip end thereof. Meanwhile, the plurality of gas nozzles 16 may protrude from the top wall 11 and/or the side wall 12.

The gas introducing pipes 17 are provided in the top wall 11, and supply a second gas from gas supply holes 17a formed in the lower surface thereof. Therefore, the second gas is supplied from a position higher than that of the first gas. Meanwhile, the gas introducing pipes 17 may be provided in the top wall 11 and/or the side wall 12.

A gas supply source 31 is used as a gas supply source of, for example, a plasma generation rare gas, or a gas used for an oxidation processing, a nitriding processing, a film forming processing, an etching processing, or an ashing processing. For example, the second gas that hardly decomposes is introduced from the plurality of gas introducing pipes 17, and the first gas that easily decomposes is introduced from the plurality of gas nozzles 16. For example, among N₂ gas and silane gas used when forming a SiN film, N₂ gas that hardly decomposes is introduced from the plurality of gas introducing pipes 17, and silane gas that easily decomposes is introduced from the plurality of gas nozzles 16. Therefore, a SiN film having good quality may be formed by not excessively dissociating silane gas that easily decomposes.

The gas supply mechanism 3 includes a gas supply device 3a including the gas supply source 31, a pipe 32a that connects the gas supply source 31 and the plurality of gas nozzles 16, and a pipe 32b that connects the gas supply source 31 and the plurality of gas introducing pipes 17. In FIG. 1, although one gas supply source 31 is illustrated, the gas supply device 3a may include a plurality of gas supply sources depending on the type of gas used.

The gas supply device 3a further includes a mass flow controller and an opening/closing valve (not illustrated) provided in the middle of the pipes 32a and 32b. The types of gases supplied into the processing container 2 or the flow rates of the gases are controlled by the mass flow controller and the opening/closing valve.

Each of the components of the plasma processing apparatus 1 is connected to the control unit 8, respectively, and is controlled by the control unit 8. Typically, the control unit 8 may be, for example, a computer. In the example illustrated in FIG. 2, the control unit 8 includes a process controller 81 provided with a CPU, a user interface 82 connected to the process controller 81, and a storage unit 83.

The process controller 81 is a control means configured to collectively control each component involved in, for example, process conditions such as temperature, pressure, a gas flow rate, a bias application radio-frequency power, and a microwave output in the plasma processing apparatus 1. Each of the components may be, for example, the radio-frequency bias power source 25, the gas supply device 3a, the exhaust device 4, and the microwave introducing module 5.

The user interface 82 includes, for example, a keyboard or a touch panel for inputting, for example, commands by a process manager to manage the plasma processing apparatus 1, and a display for visually displaying the operation status of the plasma processing apparatus 1.

The storage unit 83 stores a control program for realizing various processings executed in the plasma processing apparatus 1 by the control of the process controller 81, or recipe in which a processing condition data is recorded. The process controller 81 calls and executes an arbitrary control program or recipe from the storage unit 83 as needed, for example, an instruction from the user interface 82. Therefore, a desired processing is performed in the processing container 2 of the plasma processing apparatus 1 under the control of the process controller 81.

The control program and the recipe described above that are stored in, for example, a computer readable storage medium such as a flash memory, a DVD, a Blue-ray disc may be used. Further, it is possible to transmit the above recipe from another device through, for example, a dedicated line at any time and use it on-line.

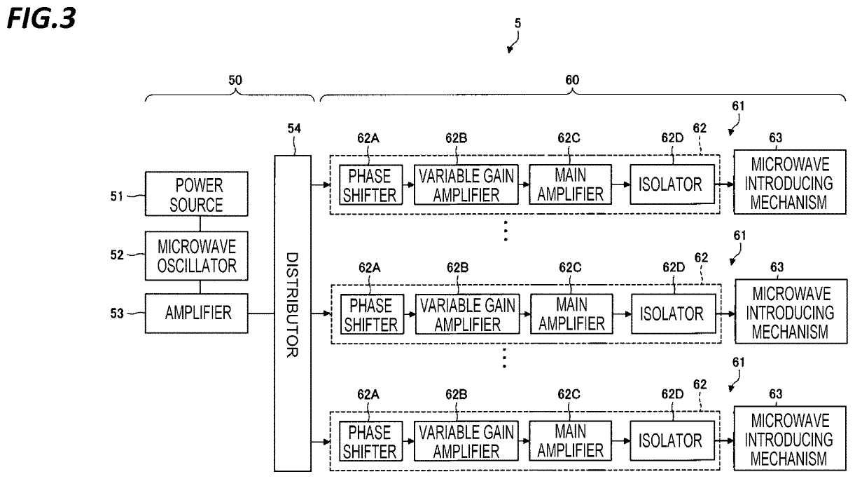

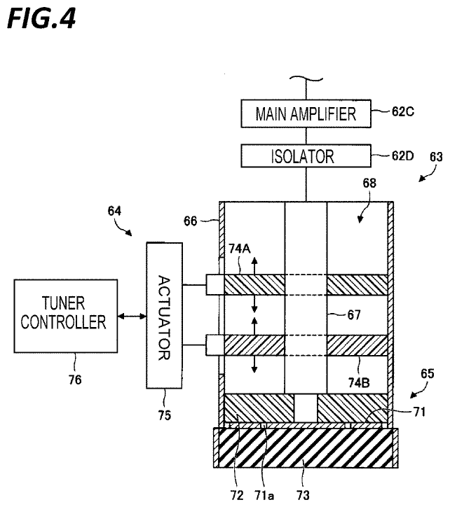

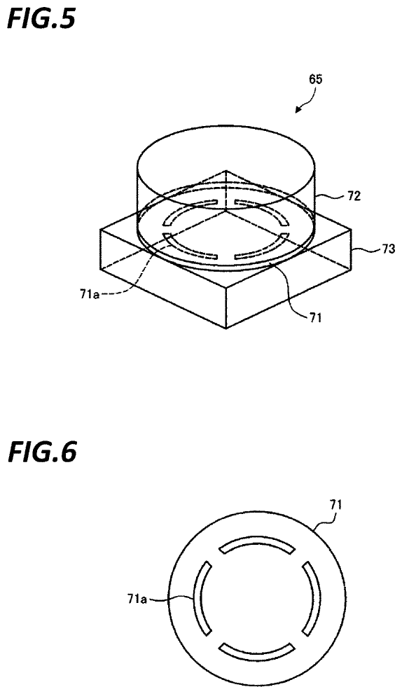

Next, a configuration of the microwave introducing module 5 will be described with reference to FIGS. 1 to 6. FIG. 3 is an explanation view illustrating the configuration of the microwave introducing module illustrated in FIG. 1. FIG. 4 is a cross-sectional view illustrating a microwave introducing mechanism 63 illustrated in FIG. 3. FIG. 5 is a perspective view illustrating an antenna of the microwave introducing mechanism 63 illustrated in FIG. 4. FIG. 6 is a plan view illustrating a planar antenna of the microwave introducing mechanism 63 illustrated in FIG. 4.

The microwave introducing module 5 is provided above the processing container 2, and introduces an electromagnetic wave (microwave) into the processing container 2. As illustrated in FIG. 1, the microwave introducing module 5 includes the top wall 11 that is a conductive member, a microwave output unit 50, and an antenna unit 60. The top wall 11 is disposed above the processing container 2 and includes a plurality of openings. The microwave output unit 50 generates a microwave and distributes the microwave to a plurality of paths to output. The antenna unit 60 introduces the microwave output from the microwave output unit 50 to the processing container 2. In the embodiment, the top wall 11 of the processing container 2 also functions as a conductive member of the microwave introducing module 5.

As illustrated in FIG. 3, the microwave output unit 50 includes a power source 51, a microwave oscillator 52, an amplifier 53 that amplifies the microwave oscillated by the microwave oscillator 52, and a distributor 54 that distributes the microwave amplified by the amplifier 53 to a plurality of paths. The microwave generator 52 oscillates a microwave with a predetermined frequency (e.g., 2.45 GHz). The frequency of the microwave is not limited to 2.45 GHz, and may be, for example, 8.35 GHz, 5.8 GHz, or 1.98 GHz. Further, the microwave output unit 50 may be applied to a case where the frequency of the microwave is within a range of 800 MHz to 1 GHz, for example, 860 MHz. The distributor 54 distributes the microwave while matching the impedances of the input side and the output side.

The antenna unit 60 includes a plurality of antenna modules 61. The plurality of antenna modules 61 introduce the microwave distributed by the distributor 54 into the processing container 2, respectively. In the embodiment, the configurations of the plurality of antenna modules 61 are all equal to each other. Each antenna module 61 includes an amplifier unit 62 that mainly amplifies and outputs the distributed microwave, and the microwave introducing mechanism 63 that introduces the microwave output from the amplifier unit 62 into the processing container 2.

The amplifier unit 62 includes a phase shifter 62A, a variable gain amplifier 62B, a main amplifier 62C, and an isolator 62D. The phase shifter 62A changes the phase of the microwave. The variable gain amplifier 62B adjusts a power level of the microwave input to the main amplifier 62C. The main amplifier 62C is configured as a solid state amplifier. The isolator 62D separates the reflected microwave that is reflected by the antenna of the microwave introducing mechanism 63 and is directed to the main amplifier 62C.

The phase shifter 62A changes the phase of the microwave to change the radiation characteristic of the microwave. The phase shifter 62A is used, for example, to control the directivity of the microwave by adjusting the phase of the microwave for each antenna module 61 and to change the distribution of the plasma. The phase shifter 62A may not be provided when the adjustment of the radiation characteristic is not performed.

The variable gain amplifier 62B is used for adjusting variations in the individual antenna module 61 or adjusting plasma intensity. For example, the distribution of the plasma in the entire inside of the processing container 2 may be adjusted by changing the variable gain amplifier 62B for each antenna module 61.

The main amplifier 62C includes, for example, an input matching circuit, a semiconductor amplification element, an output matching circuit, and a high-Q resonance circuit, which are not illustrated. As a semiconductor amplification element, for example, GaAsHEMT, GaNHEMT, laterally diffused (LD)-MOS capable of an E-class operation are used.

The isolator 62D includes a circulator and a dummy load (coaxial terminator). The circulator guides the reflected microwave that is reflected by the antenna of the microwave introducing mechanism 63 to the dummy load. The dummy load converts the reflected microwave guided by the circulator into heat. As described above, in the embodiment, the plurality of antenna modules 61 are provided, and a plurality of microwaves introduced into the processing container 2 by the respective microwave introducing mechanisms 63 of the plurality of antenna modules 61 is synthesized in the processing container 2. As a result, the individual isolator 62D may be small, and thus, the isolator 62D may be provided adjacent to the main amplifier 62C.

As illustrated in FIG. 1, the plurality of microwave introducing mechanisms 63 are provided in the top wall 11. As illustrated in FIG. 4, the microwave introducing mechanism 63 includes a tuner 64 configured to match an impedance, and an antenna 65 configured to radiate the amplified microwave into the processing container 2. Further, the microwave introducing mechanism 63 includes a main container 66 made of a metal material and having a cylindrical shape extending in the vertical direction in FIG. 4, and an inner conductor 67 extending in the main container 66 in the same direction as the direction in which the main container 66 extends. The main container 66 and the inner conductor 67 constitute a coaxial pipe. The main container 66 constitutes an outer conductor of the coaxial pipe. The inner conductor 67 has a rod shape or a cylindrical shape. A space between the inner peripheral surface of the main container 66 and the outer peripheral surface of the inner conductor 67 forms a microwave transmission path 68.

The antenna module 61 further includes a power feeding converter (not illustrated) provided on the base end side (upper end side) of the main container 66. The power feeding converter is connected to the main amplifier 62C via a coaxial cable. The isolator 62D is provided in the middle of the coaxial cable. The antenna 65 is provided on the side of the main container 66 opposite to the power feeding converter. As will be described later, a portion of the main container 66 closer to the base end side than the antenna 65 is within the impedance adjustment range by the tuner 64.

As illustrated in FIGS. 4 and 5, the antenna 65 includes a planar antenna 71 connected to the lower end portion of the inner conductor 67, a microwave delaying material 72 disposed on the upper surface side of the planar antenna 71, and a microwave transmitting plate 73 disposed on the lower surface side of the planar antenna 71. The lower surface of the microwave transmitting plate 73 is exposed to the inner space of the processing container 2. The microwave transmitting plate 73 is fitted into the opening of the top wall 11 that is the conductive member of the microwave introducing module 5, through the main container 66. The microwave transmitting plate 73 corresponds to a microwave transmitting window in the embodiment.

The planar antenna 71 has a disc shape. Further, the planar antenna 71 includes a slot 71a formed to penetrate the planar antenna 71. In the example illustrated in FIGS. 5 and 6, four slots 71a are provided, and each slot 71a has an arc shape that is equally divided into four pieces. The number of slots 71a is not limited to four, and may be five or more, or one or more, or three or less.

The microwave delaying material 72 is made of a material having a dielectric constant larger than that of vacuum. As a material for forming the microwave delaying material 72, for example, quartz, ceramics, a fluorine resin such as a polytetrafluoroethylene resin, or a polyimide resin may be used. The wavelength of the microwave lengthens in vacuum. The microwave delaying material 72 has a function of adjusting a plasma by shortening the wavelength of the microwave. Further, the phase of the microwave changes depending on the thickness of the microwave delaying material 72. As a result, it is possible to adjust the planar antenna 71 to an antinode position of the standing wave by adjusting the phase of the microwave depending on the thickness of the microwave delaying material 72. Therefore, it is possible to suppress the reflected wave by the planar antenna 71, and to increase the radiant energy of the microwave radiated from the planar antenna 71. That is, therefore, it is possible to efficiently introduce the power of the microwave into the processing container 2.

The microwave transmitting plate 73 is made of a dielectric material. As a dielectric material for forming the microwave transmitting plate 73, for example, quartz or ceramics may be used. The microwave transmitting plate 73 forms a shape capable of efficiently radiating the microwave in a transverse electric (TE) mode. In the example in FIG. 5, the microwave transmitting plate 73 has a rectangular parallelepiped shape. The shape of the microwave transmitting plate 73 is not limited to the rectangular parallelepiped shape, and may be, for example, a columnar shape, a pentagonal prism shape, a hexagonal prism shape, or an octagonal prism shape.

In the microwave introducing mechanism 63 with such a configuration, the microwave amplified by the main amplifier 62C reaches the planar antenna 71 through the microwave transmission path 68 between the inner peripheral surface of the main container 66 and the outer peripheral surface of the inner conductor 67. Then, the microwave is transmitted from the slot 71a of the planar antenna 71 through the microwave transmitting plate 73 and is radiated to the internal space of the processing container 2.

The tuner 64 constitutes a slug tuner. Specifically, as illustrated in FIG. 4, the tuner 64 includes two slugs 74A and 74B disposed on a portion of the main container 66 closer to the base end side (upper end side) than the antenna 65. The tuner 64 further includes an actuator 75 configured to operate the two slugs 74A and 74B, and a tuner controller 76 configured to control the actuator 75.

The slugs 74A and 74B have a plate shape or an annular shape, and are disposed between the inner peripheral surface of the main container 66 and the outer peripheral surface of the inner conductor 67. Further, the slugs 74A and 74B are made of a dielectric material. As a dielectric material for forming the slugs 74A and 74B, for example, high-purity alumina having a relative dielectric constant of 10 may be used. Since high-purity alumina has a larger relative dielectric constant than quartz (relative dielectric constant of 3.88) or Teflon (registered trademark) (relative dielectric constant of 2.03) that are usually used as materials for forming a slug, the thickness of the slugs 74A and 74B may be reduced. Further, high-purity alumina has a smaller dielectric loss tangent (tans) than quartz or Teflon (registered trademark), and has a characteristic that microwave loss may be reduced. High-purity alumina is further characterized by low distortion and heat resistance. As high-purity alumina, an alumina sintered body having a purity of 99.9% or more may be used. Further, as high-purity alumina, single crystal alumina (sapphire) may be used.

The tuner 64 moves the slugs 74A and 74B in the vertical direction by the actuator 75 based on a command from the tuner controller 76. Therefore, the tuner 64 adjusts the impedance. For example, the tuner controller 76 adjusts the position of the slugs 74A and 74B such that the impedance of the terminal end portion is, for example, 50Ω.

In the embodiment, the main amplifier 62C and the tuner 64, and the planar antenna 71 are disposed close to each other. Particularly, the tuner 64 and the planar antenna 71 constitute a lumped constant circuit, and function as a resonator. Impedance mismatch exists in the attaching portion of the planar antenna 71. In the embodiment, the tuner 64 enables highly accurate tuning including a plasma, and thus, the influence of reflection on the planar antenna 71 may be eliminated. Further, the tuner 64 may eliminate the impedance mismatch up to the planar antenna 71 with high accuracy, and thus, substantially the mismatched portion may become a plasma space. Therefore, the tuner 64 enables highly accurate plasma control.

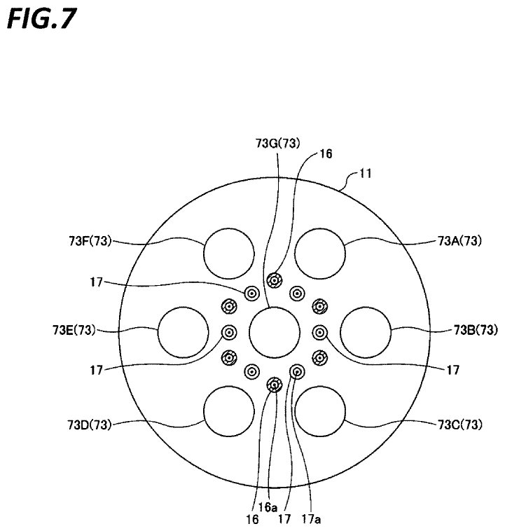

Next, the bottom surface of the top wall 11 of the processing container 2 illustrated in FIG. 1 will be described with reference to FIG. 7. FIG. 7 is a view illustrating an example of a bottom surface of the top wall 11 of the processing container 2 illustrated in FIG. 1. In the following descriptions, it is assumed that the microwave transmitting plate 73 has a columnar shape.

The microwave introducing module 5 includes a plurality of microwave transmitting plates 73. As described above, the microwave transmitting plate 73 corresponds to the microwave transmitting window. The plurality of microwave transmitting plates 73 are disposed on one virtual plane in parallel with the placing surface 21a of the stage 21 in a state of being fitted into the plurality of openings in the top wall 11 that is a conductive member of the microwave introducing module 5. Further, the plurality of microwave transmitting plates 73 include three microwave transmitting plates 73 having the same or substantially the same distance from the center point on the virtual plane. Having substantially the same distance from the center point means that the position of the microwave transmitting plate 73 may be slightly shifted from the desired position from the viewpoint of, for example, the shape accuracy of the microwave transmitting plate 73 or the assembly accuracy of the antenna module 61 (microwave introducing mechanism 63).

In the embodiment, the plurality of microwave transmitting plates 73 include seven microwave transmitting plates 73 disposed to be a hexagonal closest packing arrangement. Specifically, the plurality of microwave transmitting plates 73 include seven microwave transmitting plates 73A to 73G. Among them, six microwave transmitting plates 73A to 73F are disposed such that the center points thereof coincide with or substantially coincide with the vertices of the regular hexagon, respectively. One microwave transmitting plate 73G is disposed such that the center point thereof coincides with or substantially coincides with the center of the regular hexagon. Substantially coinciding with the vertices or the center point means that the center point of the microwave transmitting plate 73 may be slightly shifted from the above vertices or the center from the view point of, for example, the shape accuracy of the microwave transmitting plate 73 or the assembly accuracy of the antenna module 61 (microwave introducing mechanism 63).

As illustrated in FIG. 7, the microwave transmitting plate 73G is disposed in the central portion of the top wall 11. The six microwave transmitting plates 73A to 73F are disposed outside the central portion of the top wall 11 so as to surround the microwave transmitting plate 73G. Therefore, the microwave transmitting plate 73G corresponds to the central microwave transmitting window, and the microwave transmitting plates 73A to 73F correspond to the outer microwave transmitting windows. In the embodiment, “the central portion of the top wall 11” means “the central portion of the top wall 11 in the planar shape.”

In the embodiment, in all the microwave transmitting plates 73, the distances between the center points of arbitrary three microwave transmitting plates 73 adjacent to each other are equal to, or substantially equal to each other. Six gas nozzles 16 are disposed equidistantly in the circumferential direction between the outer microwave transmitting plates 73A to 73G and the central microwave transmitting plate 73G. The gas nozzles 16 supply the first gas into the processing container 2 from the gas supply holes 16a formed at the tip end thereof. Six gas introducing pipes 17 are disposed between the six gas nozzles 16 in the circumferential direction. The gas introducing pipe 17 is disposed between adjacent gas nozzles 16. The gas introducing pipes 17 supply the second gas into the processing container 2 from the gas supply holes 17a formed at the tip end thereof.

[Structure of Gas Nozzle]

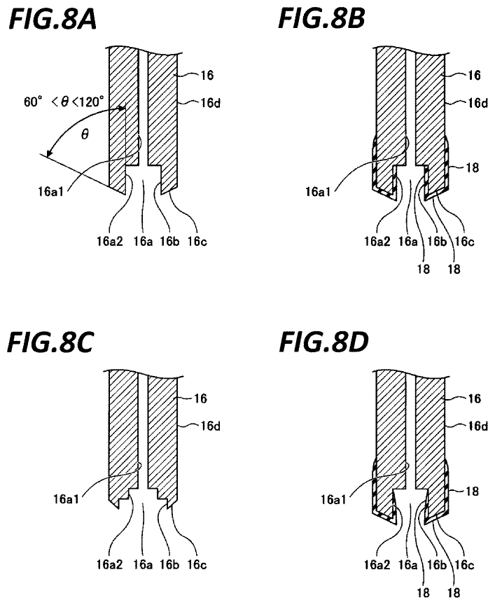

Next, the structure of the gas nozzle 16 will be described with reference to FIGS. 8A to 8D. FIGS. 8A to 8D are views illustrating examples of the structure of the gas nozzle 16 according to the embodiment. In the plasma processing apparatus 1, electromagnetic wave energy is concentrated in the vicinity of the electromagnetic wave radiation port, that is, in the vicinity of the lower surface of the top wall 11, and electron temperature tends to increase. Therefore, the gas may decompose at the tip end opening of the gas supply hole 17a and the opening may be clogged, and also the opening may be melted due to discharge at the opening. Therefore, the opening of the gas introducing pipe 17 has a dimple structure that expands from the pore of the gas supply hole 17a and opens to the processing space. By widening the opening of the gas supply hole 17a, concentration of electromagnetic wave energy may be reduced, and thus, abnormal discharge may be prevented.

Meanwhile, depending on the processing conditions, the surface wave may be propagated to the surface of the gas nozzle 16 protruding below the lower surface of the top wall 11. In this case, the gas may decompose at the opening of the gas supply hole 16a of the tip end of the gas nozzle 16 by the propagation of the surface wave and the opening may be clogged, and also the opening may be melted due to discharge at the opening. Therefore, in the embodiment, the opening of the gas nozzle 16 includes an enlarged diameter portion 16a2 that expands from a pore 16a1 of the gas supply hole 16a illustrated in FIG. 8A, and is opened to the processing space, and has a dimple structure. With this structure, it is possible to prevent a microwave from being transmitted to the gas nozzle 16 to occur abnormal discharge at the opening of the gas supply hole 16a, which adversely affects the substrate processing. In the embodiment, the enlarged diameter portion 16a2 has a cylindrical shape having a circular bottom surface.

An angle between an inner wall side surface 16b of the enlarged diameter portion 16a2 and a tip end surface 16c of the gas nozzle 16 outside the enlarged diameter portion 16a2 (hereinafter, referred to as a “dimple contact surface angle θ”) may be an angle that satisfies the condition of 60°≤θ≤120°. Therefore, the electric field concentration of the surface wave of the microwave may be reduced.

The length of the opening of the enlarged diameter portion 16a2 in the longitudinal direction may be λ_{sw}/4 or less, where λ_{sw} is the surface wave wavelength of the microwave. That is, for example, when the enlarged diameter portion 16a2 has a cylindrical shape, the diameter of the opening of the enlarged diameter portion 16a2 may be λ_{sw}/4 or less, and when the enlarged diameter portion 16a2 has an elliptical shape, the length of the major axis of the opening of the enlarged diameter portion 16a2 may be λ_{sw}/4 or less. For example, in the case of a microwave having a frequency of 860 MHz, λ_{sw} is approximately 20 mm, and thus, the opening diameter of the enlarged diameter portion 16a2 may be 5 mm or less. The length of the opening of the enlarged diameter portion 16a2 in the longitudinal direction is shortened to ¼ or less with respect to the wavelength λ_{sw} of the surface wave, and thus, the microwave is not able to enter the enlarged diameter portion 16a2, and abnormal discharge may be prevented from occurring in the vicinity of the enlarged diameter portion 16a2.

As illustrated in FIG. 8B, the inner wall side surface 16b of the enlarged diameter portion 16a2 may be coated with an insulating film 18. Further, not only the inner wall side surface 16b of the enlarged diameter portion 16a2, but also the bottom surface of the enlarged diameter portion 16a2 may be coated with the insulating film 18. Materials of the insulating film 18 may include yttria (Y₂O₃) or alumina (Al₂O₃).

Further, the tip end surface 16c outside the enlarged diameter portion 16a2 and a part of or the entire of an outer surface 16d may be further coated with the insulating film 18. Abnormal discharge is likely to occur at a place around the tip end of the gas nozzle 16 where the insulating film 18 is cut off. As a result, as illustrated in FIG. 8B, the inner wall side surface 16b of the enlarged diameter portion 16a2, the tip end surface 16c outside the enlarged diameter portion 16a2, and at least a part the outer surface 16d are coated with the insulating film 18, and thus, it is possible to prevent abnormal discharge from occurring in the gas nozzle 16.

As illustrated in FIG. 8C, the inner wall side surface 16b of the enlarged diameter portion 16a2 may have steps. Further, the steps of the inner wall side surface 16b may be coated with the insulating film 18. As illustrated in FIG. 8D, the thickness of the insulating film 18 that coats the inner wall side surface 16b of the enlarged diameter portion 16a2 may be gradually thinned from the opening end portion of the enlarged diameter portion 16a2 toward the bottom surface. Further, the bottom surface of the enlarged diameter portion 16a2 may not be coated with the insulating film 18.

[Modification]

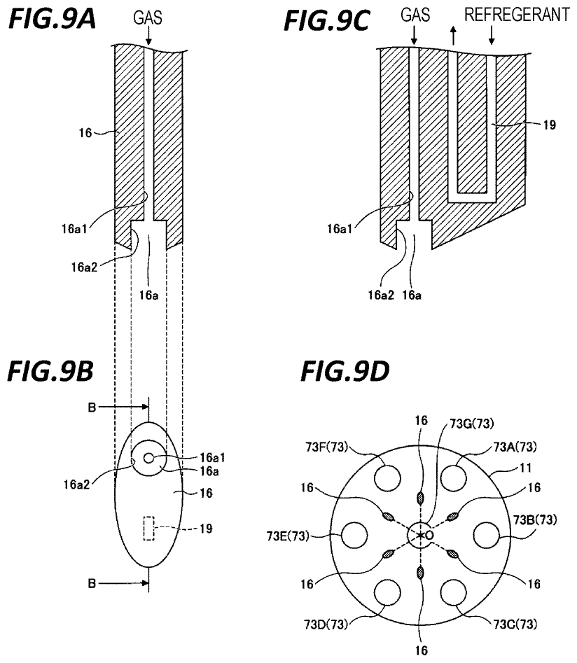

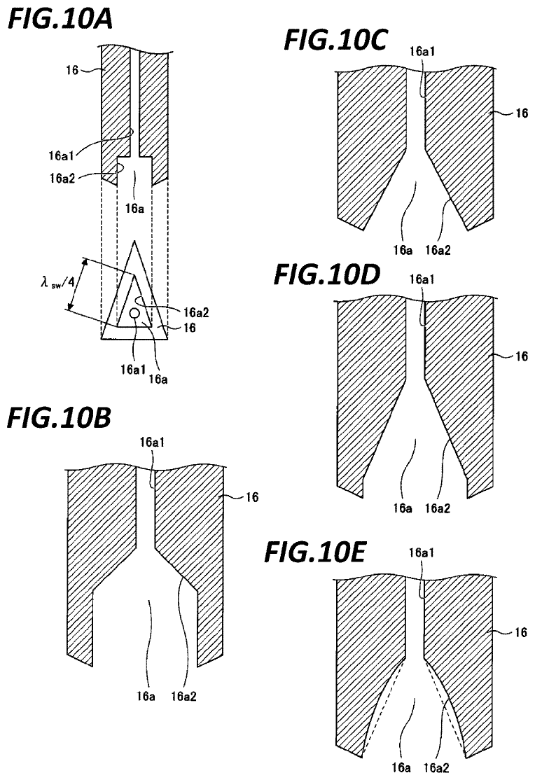

Next, gas nozzles 16 according to Modifications of the embodiment will be described with reference to FIGS. 9A to 9D and 10A to 10E. FIGS. 9A to 9D are views illustrating an example of a structure of the gas nozzle 16 according to Modification 1 of the embodiment. FIGS. 10A to 10E are views illustrating examples of a structure of the gas nozzles 16 according to Modifications 2 to 6 of the embodiment.

[Modification 1]

The structure of the gas nozzle 16 according to Modification 1 of the embodiment of FIGS. 9A to 9D will be described. As illustrated in FIG. 9A, the gas nozzle 16 according to Modification 1 also has a dimple structure that including the enlarged diameter portion 16a2 that expands from the pore 16a1, and is opened to the processing space. Therefore, it is possible to prevent abnormal discharge from occurring in the gas nozzle 16.

Further, in Modification 1, the enlarged diameter portion 16a2 has a cylindrical shape having a circular bottom surface. The lower surface of the tip end of the gas nozzle 16 according to Modification 1 is illustrated in FIG. 9B. According to this, the lower surface of the tip end of the gas nozzle 16 has an elliptical shape. That is, the surface perpendicular to the protruding direction of the gas nozzle 16 has an elliptical shape. However, the shape of the surface perpendicular to the protruding direction of the gas nozzle 16 is not limited to an elliptical shape, and may have a streamlined portion. The streamlined portion refers to a shape having a portion configured to be curved such as a head of a shark or a body shape of a fish.

A cross-sectional surface obtained by cutting the gas nozzle 16 along B-B plane taken along the longitudinal axis of the elliptical shape is illustrated in FIG. 9C. A flow path 19 configured to circulate a heat medium (e.g., coolant) is formed in the gas nozzle 16. The flow path 19 is formed in a U shape to be side by side with the pore 16a1 so as to circulate the heat medium. The flow path 19 may be formed to make a U-turn in the vicinity of the enlarged diameter portion 16a2. Therefore, it is possible to cool the entire gas nozzle 16 and remove the heat.

FIG. 9D is a view illustrating a lower surface of the top wall 11 in which six gas nozzles 16 according to Modification 1 are disposed in the circumferential direction. In the gas nozzle 16 according to Modification 1, the shape of the surface perpendicular to the protruding direction of the gas nozzle 16 includes a streamlined portion or an elliptical portion. In this case, the straight lines in the vertex direction of the streamlined shape or the elliptical shape of the gas nozzles 16 intersect with each other on the center axis O of the top wall 11. That is, the vertex direction of the streamlined shape or the elliptical shape of the gas nozzle 16 is directed toward the direction of the central microwave transmitting plate 73G. Therefore, the gas nozzle 16 is configured not to interfere with the propagation of the surface wave of the microwave.

[Modifications 2 to 6]

Next, structures of the gas nozzles 16 according to Modifications 2 to 6 of the embodiment of FIGS. 10A to 10E will be described. The gas nozzle 16 may include a portion having a polygonal cross-sectional shape perpendicular to the protruding direction, and the enlarged diameter portion 16a2 may include an opening having the same shape as the cross-sectional shape. The enlarged diameter portion 16a2 is not limited to a cylindrical shape, and may have a prismatic shape having a polygonal bottom shape such as a quadrangle or a pentagon. In the gas nozzle 16 according to Modification 2 of the embodiment of FIG. 10A, the enlarged diameter portion 16a2 has a triangular prism shape having a triangular bottom surface. Also in this case, the length of the side of the opening of the enlarged diameter portion 16a2 in the longitudinal direction may be λ_{sw}/4 or less, where λ_{sw} is the wavelength of the surface wave of the microwave. It is possible to prevent abnormal discharge from occurring in the vicinity of the enlarged diameter portion 16a2 by setting the length of the opening of the enlarged diameter portion 16a2 in the longitudinal direction to ¼ or less of the wavelength λ_{sw} of the surface wave.

The bottom portion of the enlarged diameter portion 16a2 of the gas nozzle 16 according to Modification 3 of the embodiment of FIG. 10B is not horizontal but obliquely conical, and has a shape in which a conical shape and a cylindrical shape are combined. The enlarged diameter portion 16a2 of the gas nozzle 16 according to Modification 4 of the embodiment of FIG. 10C has a conical shape and does not have a cylindrical shape. The enlarged diameter portion 16a2 of the gas nozzle 16 according to Modification 5 of the embodiment of FIG. 10D has a tip end that extends vertically by approximately 1 mm with respect to the enlarged diameter portion 16a2 of FIG. 10C.

The wall surface of the enlarged diameter portion 16a2 may be curved outward from a conical shape, as illustrated in the gas nozzle 16 according to Modification 6 of the embodiment of FIG. 10E. However, the enlarged diameter portion 16a2 is not curved inward from a conical shape. It is because, when the wall surface of the enlarged diameter portion 16a2 is curved inward, at the time of introducing the gas from the enlarged diameter portion 16a2 into the plasma processing space, the gas spreads outward and is easily diffused, and it becomes difficult to control the gas density distribution in the plasma processing space.

According to an aspect, it is possible to prevent abnormal discharge in the gas nozzle.

From the foregoing, it will be appreciated that various embodiments of the present disclosure have been described herein for purposes of illustration, and that various modifications may be made without departing from the scope and spirit of the present disclosure. Accordingly, the various embodiments disclosed herein are not intended to be limiting, with the true scope and spirit being indicated by the following claims.

What is claimed is:

1. A plasma processing apparatus comprising:
a processing container; and
a plurality of gas nozzles protruding from at least one of a top wall and a side wall that constitute the processing container, and each including a gas supply hole configured to supply a gas into the processing container,
wherein each of the plurality of gas nozzles includes an enlarged diameter portion that is enlarged from a pore of the gas supply hole at a tip end of the gas supply hole and is opened to a processing space.

2. The plasma processing apparatus according to claim 1, wherein an angle θ between an inner wall side surface of the enlarged diameter portion and a tip end surface of the gas nozzle is 60°≤θ≤120°.

3. The plasma processing apparatus according to claim 2, further comprising:
a plasma generator disposed above the processing container and configured to introduce an electromagnetic wave into the processing container thereby generating a plasma,
wherein the plurality of gas nozzles protrudes from the top wall.

4. The plasma processing apparatus according to claim 3, wherein a length of an opening of the enlarged diameter portion in a longitudinal direction is λ_{sw}/4 or less, where λ_{sw} is a wavelength of a surface wave of a microwave.

5. The plasma processing apparatus according to claim 4, wherein each of the plurality of gas nozzles has a portion in which a surface perpendicular to a protruding direction is elliptical or streamlined, and
straight lines in a long axis direction of the ellipses or a vertex direction of the streamlined portions of the plurality of gas nozzles intersect with each other at a center point of the top wall of the processing container.

6. The plasma processing apparatus according to claim 5, wherein each of the plurality of gas nozzles has a flow path configured to circulate a heat medium.

7. The plasma processing apparatus according to claim 4, wherein each of the plurality of gas nozzles has a polygonal cross-section that is perpendicular to a protruding direction, and
the enlarged diameter portion has an opening having a same shape as the polygonal cross-section.

8. The plasma processing apparatus according to claim 7, wherein an inner wall of the enlarged diameter portion is coated with an insulating film.

9. The plasma processing apparatus according to claim 8, wherein the tip end portion and at least a part of a side wall of each of the plurality of gas nozzles are coated with an insulating film.

10. The plasma processing apparatus according to claim 1, further comprising:
a plasma generator disposed above the processing container and configured to introduce an electromagnetic wave into the processing container thereby generating a plasma,
wherein the plurality of gas nozzles protrudes from the top wall.

11. The plasma processing apparatus according to claim 10, wherein a length of an opening of the enlarged diameter portion in a longitudinal direction is λ_{sw}/4 or less, where λ_{sw} is a wavelength of a surface wave of a microwave.

12. The plasma processing apparatus according to claim 1, wherein each of the plurality of gas nozzles has a portion in which a surface perpendicular to a protruding direction is elliptical or streamlined, and
straight lines in a long axis direction of the ellipses or a vertex direction of the streamlined portions of the plurality of gas nozzles intersect with each other at a center point of the top wall of the processing container.

13. The plasma processing apparatus according to claim 12, wherein each of the plurality of gas nozzles has a flow path configured to circulate a heat medium.

14. The plasma processing apparatus according to claim 1, wherein each of the plurality of gas nozzles has a polygonal cross-section that is perpendicular to a protruding direction, and
the enlarged diameter portion has an opening having a same shape as the polygonal cross-section.

15. The plasma processing apparatus according to claim 1, wherein an inner wall of the enlarged diameter portion is coated with an insulating film.

16. The plasma processing apparatus according to claim 1, wherein the tip end portion and at least a part of a side wall of each of the plurality of gas nozzles are coated with an insulating film.
